(19) United States
(12) Patent Application Publication
(10) Pub. No.: US 2014/0242520 A1
(43) Pub. Date: Aug. 28, 2014

(54) I-LINE PHOTORESIST COMPOSITION AND METHOD FOR FORMING FINE PATTERN USING SAME

(71) Applicant: DONGJIN SEMICHEM CO., LTD., Incheon (KR)

(72) Inventors: Jung-Youl Lee, Anyang-si (KR); Eu-Jean Jang, Hwaseong-si (KR); Jae-Woo Lee, Bucheon-si (KR); Jae-Hyun Kim, Seoul (KR)

(21) Appl. No.: 14/346,356

(22) PCT Filed: Sep. 21, 2012
(86) PCT No.: PCT/KR2012/007576

§ 371 Date: Mar. 21, 2014

(30) Foreign Application Priority Data
Sep. 22, 2011 (KR) 10-2011-0095754

(51) Int. Cl. G03F 7/038

(52) U.S. Cl. CPC G03F 7/0388
USPC 430/285.1; 430/287.1; 430/325

(57) ABSTRACT

An I-line photoresist composition, having excellent thermal stability at high temperature of 200-250° C., by which fine photoresist patterns form using an acid diffusion layer and a method for forming a fine pattern using the same, comprising: a polymer containing 1-99 mol % of repeating unit selected from a group consisting of 1-99 mol % of repeating unit represented by Formula 1, repeating unit represented by Formula 2, repeating unit represented by Formula 3 and mixture thereof; a photo active compound containing at least two diazonaphtoquinone (DNQ) groups; and an organic solvent. Formulas 1-3 are located in the specification. R* and R** are independently a hydrogen atom or a methyl group. R₁ is a hydrogen atom or linear, branch or cyclic hydrocarbonyl group of 3-15 carbon atoms, containing or not containing 1-4 oxygen atoms. R₂ is linear, branch or cyclic hydrocarbonyl group of 1-30 carbon atoms, containing or not containing 1-4 oxygen atoms.

### FIELD OF THE INVENTION

This invention relates to an I-line photoresist composition and a method of forming a fine pattern using the same, and more particularly to an I-line photoresist composition which has a excellent thermal stability at high temperature of 200 to 250° C. and by which fine photoresist patterns using an acid diffusion layer can be formed and method of forming a fine pattern using the same.

### BACKGROUNDS OF THE INVENTION

A down-scale and higher integration degree of the semiconductor devices has required a technique for realizing fine patterns. Among methods for forming fine patterns of the semiconductor device, it is the best effective method to use the fine photoresist patterns, which is obtained through development of the exposure instrument and an introduction of an additional process.

A directed self assembly (DSA) lithography using a self-assembly of a block copolymer (BCP), among the additional processes, is expected to be capable of forming fine patterns having a line width of 20 nm and less than, which is known as the limit of a conventional optical pattern forming method.

The DSA lithography, in association with the conventional photoresist pattern process, changes a random orientation of the BCP to an ordered orientation, thereby forming the fine patterns of the semiconductor devices. In detail, for the ordered orientation of BCP, BCP is coated on a wafer or a thin film of ITO glass on which the photoresist patterns are formed, and then heated to form the BCP coating layer. The BCP coating layer is subject to a heating treatment at a temperature over a glass transition temperature (Tg) and is rearranged so a self-assembled pattern with an ordered orientation can be obtained.

Accordingly, the study for making patterns of an ordered orientation using the DSA lithography has been actively conducted. Specifically, in comparison with the effort for exploiting new lithography instrument or a conventional process, the DSA lithography is useful in view of efficient cost-down of the minimized and integrated semiconductor device and LCD. In the DSA lithography, a guide pattern is formed using a conventional ArF, KrF and I-line photoresist composition, preferably I-line photoresist composition (photoresist materials which use the I-line (365 nm) as a light source), a space between the guide patterns is covered with BCP and a heating treatment is performed to form fine patterns with ordered orientation of BCP.

However, the DSA lithography necessitates the heating treatment at 200 to 250° C. (a temperature over Tg of BCP) and thus the DSA lithography is not applicable to a process of forming the guide pattern by using the conventional I-line photoresist composition containing novolac resin with poor thermal stability.

The conventional I-line photoresist composition is not a chemically amplified resist composition which is used to form patterns through an acid-diffusion process by using a photo acid generator (PAG). In forming the patterns by using the conventional I-line photoresist composition, a dissolution inhibitor by a reaction of a conventional polymer having novolac structure with a photo active compound (PAC) is used and a contrast difference (developing rate difference) between the exposed part and unexposed part is used. Accordingly, additional processes for forming fine patterns using the acid diffusion layer (coating over the photoresist patterns an aqueous composition containing acid component and then heating and developing the resultant with the photoresist patterns) cannot be applicable to the patterns formed by using the conventional I-line photoresist composition.

### SUMMARY OF THE INVENTION

Therefore, it is an object of the present invention to provide an I-line photoresist composition having a good thermal stability so that reflow of photoresist patterns is not generated during an additional thermal heating process after forming photoresist patterns.

It is another object of the present invention to provide an I-line photoresist composition by which fine photoresist patterns using an acid diffusion layer can be formed.

In order to achieve these objects, the present invention provides an I-line photoresist composition comprising: a polymer containing 1 to 99 mol % of repeating unit selected from a group consisting of 1 to 99 mol % of repeating unit represented by a following Formula 1, a repeating unit represented by a following Formula 2, a repeating unit represented by a following Formula 3 and mixture thereof; a photo active compound containing at least two diazonaphtoquinone (DNQ) groups; and an organic solvent.

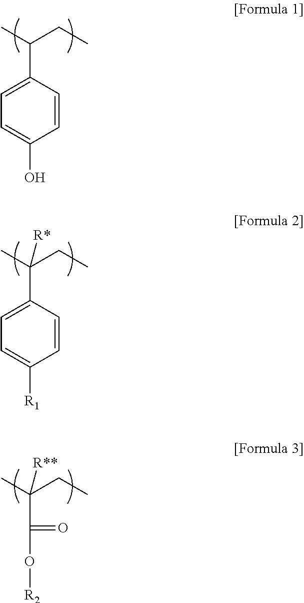

In Formulas 2 and 3, R* and R** each is independently a hydrogen atom or a methyl group, R₁ is a hydrogen atom or linear, branch or cyclic hydrocarbonyl group of 3 to 15 carbon atoms, which contains 1 to 4 oxygen atoms or does not contains, R₂ is linear, branch or cyclic hydrocarbonyl group of 1 to 30 carbon atoms, which contains 1 to 4 oxygen atoms or does not contains.

The I-line photoresist composition of the present invention has an excellent thermal stability at high temperature (200 to 250° C.) and by which fine photoresist patterns using an acid diffusion layer can be formed. After forming an aqueous polymer layer containing an acid component (acid diffusion layer) on a wafer on which line-and-space patterns are formed by using the I-line photoresist composition of the present invention, heating treatment is performed to advance the acid diffusion and then developing is performed. Therefore the patterns having a line width of 1 μm and more shifts to the fine patterns having a line width of 0.2 μm. The I-line photoresist composition of the present invention contains not a conventional polymer of novolac structure but a polymer having a protective group, thus such an acid diffusion process is possible and as a result, pattern having the line width beyond the limit of current lithography instruments can be formed.

The patterns formed by the present photoresist composition have the excellent thermal stability, thus the reflow caused by the poor thermal stability can be prevented. Also, the patterns formed by the present photoresist composition can be economically used as the guide pattern, in forming patterns having the line width of 20 nm and less than by using the DSA lithography.

### BRIEF DESCRIPTION OF THE DRAWINGS

FIG. 1 is a drawing of showing a photograph of scanning electron microscope (SEM) of a photoresist pattern according to Example 2-1 of the present invention.

FIG. 2 is a drawing of showing a photograph of SEM of a photoresist pattern according to Example 3-1 of the present invention.

FIG. 3 is a drawing of showing a photograph of SEM of a photoresist pattern according to Comparative Example 3 of the present invention.

FIG. 4 is a drawing of showing a photograph of SEM of a photoresist pattern (fine pattern) according to Example 4-1 of the present invention.

### DETAILED DESCRIPTION OF THE INVENTION

A more complete appreciation of the invention, and many of the attendant advantages thereof, will be better appreciated by reference to the following detailed description.

The I-line photoresist composition of the present invention is used for a process of forming photoresist patterns using I-line (365 nm) as the light source. The I-line photoresist composition of the present invention comprises: a polymer containing 1 to 99 mol % of repeating unit selected from a group consisting of 1 to 99 mol % of repeating unit represented by a following Formula 1, a repeating unit represented by a following Formula 2, a repeating unit represented by a following Formula 3 and mixture thereof; a photo active compound containing at least two diazonaphtoquinone (DNQ) groups; and an organic solvent.

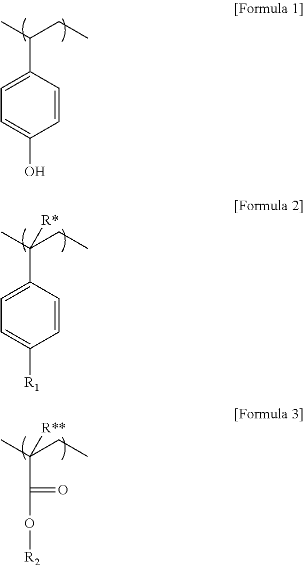

In Formulas 2 and 3, R* and R** each is independently a hydrogen atom or a methyl group, R₁ is a hydrogen atom or linear, branch or cyclic hydrocarbonyl group of 3 to 15 carbon atoms, preferably 4 to 10 carbon atoms, which contains 1 to 4 oxygen atoms or does not contains. Examples of R₁ include 1-(1-ethoxy-ethoxy) group, 1-(1-tetrabutyloxy-ethoxy) group, 1-(1-cyclohexyloxy-ethoxy) group, tetrabutoxy group, carbonic acid tetrabutyl ester group, carbonic acid 1,1-dimethyl-propyl ester group. R₂ is linear, branch or cyclic hydrocarbonyl group of 1 to 30 carbon atoms, preferably 1 to 15 carbon atoms, which contains 1 to 4 oxygen atoms, preferably 1 to 2 oxygen atoms or does not contains. Examples of R₂ include methyl group, methoxy group, ethyl group, ethoxy group, n-propyl group, isopropyl group, n-butyl group, isobutyl group, tetrabutyl group, n-penthyl group, isopenthyl group, 2-methylbutyl group, n-hexyl group, isohexyl group, 2,3-dimethyl-2butyl group, cyclohexyl group, n-heptane group, norbornene group, 7-oxa-bicyclo[2.2.1]heptane group, n-octane group, n-decane group, adamantane group, octahydro-4,7-methano-indene group, dinorbornene group, dihydrofuran-2-one group, tetrahydropyran-2-one group, oxepan-2-one group, 4-oxa-tricyclo[4.2.1.0^{3,7}]nonane-5-one group, 4,8-dioxa-tricyclo[4.2.1.0^{3.7}]nonane-5-one group, 5-oxa-tricyclo[5.2.1.0^{3,8}]decane-4-one group, 5,9-dioxa-tricyclo[5.2.1.0^{3,8}]decane-4-one group, methyl-cyclopentane group, ethyl-cyclopentane group, isopropyl-cyclopentane group, methyl-cyclohexane group, ethyl-cyclohexane group, isopropyl-cyclohexane group, 2-methyl-adamantane group, 2-ethyl-adamantane group, 2-isopropyl-adamantane group, methane-methoxy group, methane-tetrabutoxy group, methane-cyclohexyl group.

The polymer used in the present invention contains a protection group which is deprotected by an acid in the molecule and reduces a solubility of the resist layer by a diazo coupling reaction of the PAC and hydroxy in the polymer. Also, with the polymer, it is possible to form patterns by using a decomposition reaction of diazo coupling by using a light source. Also a chemical acid-amplification reaction, that is a deprotection reaction of acetal by the TAC, an acid catalyst such as the PAG, is generated. The Examples of the polymer include polymers represented by following Formulas 1a to 1d.

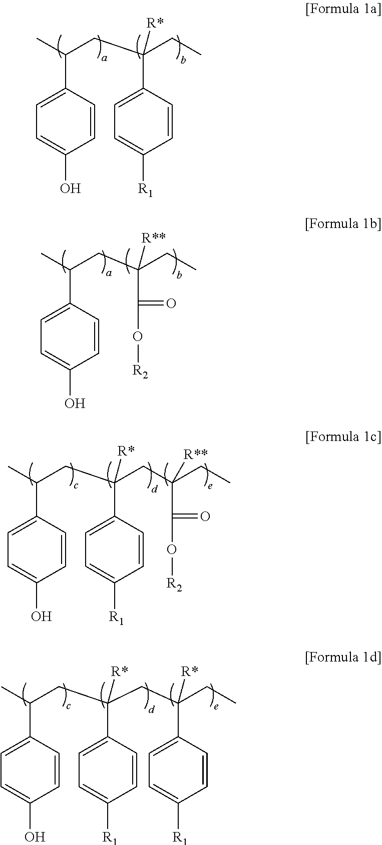

In Formulas 1a to 1d, R*, R**, R₁ and R₂ each is independently the same as defined in the Formulas 2 and 3. a, b, c, d and e represent mol % of repeating unit constituting the polymer, a is 1 to 99 mol %, preferably 10 to 90 mol %, more preferably 60 to 90 mol %, most preferably 75 to 85 mol %, b is 1 to 99 mol %, preferably 10 to 90 mol %, more preferably 10 to 40 mol %, most preferably 15 to 25 mol %. c is 1 to 98 mol %, preferably 5 to 90 mol %, more preferably 60 to 90 mol %, most preferably 75 to 85 mol %, d and e each is independently 1 to 98 mol %, preferably 5 to 90 mol %, more preferably 5 to 35 mol %, most preferably 7.5 to 17.5 mol %.

In the polymer, when mol % of repeating unit represented by Formula 1 (repeating unit of a and c) is too low (or mol % of repeating unit represented by Formulas 2 and 3 (repeating unit of b, d and e) is too high), the dissolution rate of polymer at the developing step after exposing I-line is not sufficient so that the patterns may not be formed. When mol % of repeating unit represented by Formula 1 (repeating unit of a and c) is too high (or mol % of repeating unit represented by Formulas 2 and 3 (repeating unit of b, d and e) is too low), a trimming degree of patterns at the pattern minimization step may be low.

Examples of polymers represented by Formulas 1a to 1d include polymers represented by following Formulas 2a to 2f.

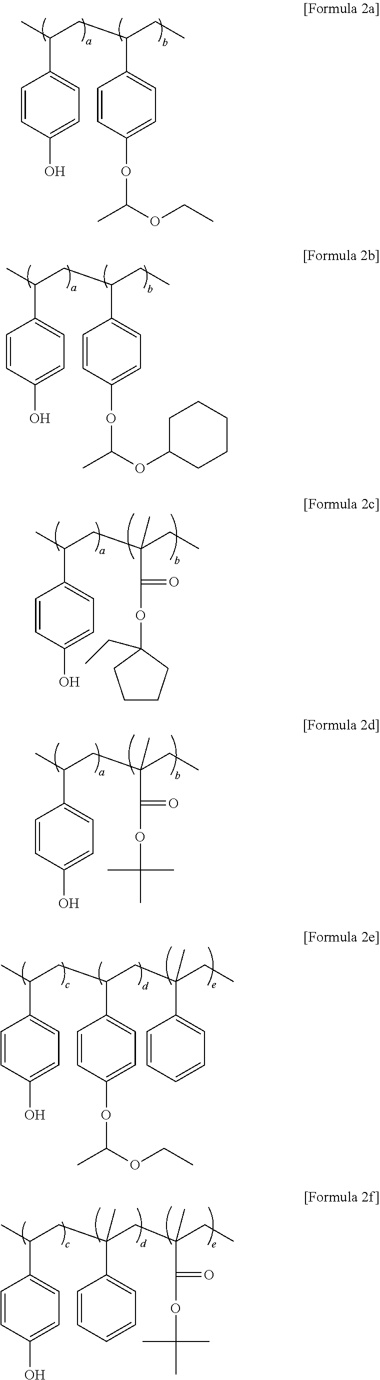

In Formulas 2a to 2f, a, b, c, d and e are the same as defined in Formulas 1a to 1d.

The amount of the polymer is 5 to 50 weight %, preferably 10 to 30 weight %, more preferably 15 to 25 weight %, with respect to total I-line photoresist composition. When the amount of the polymer is less than 5 weight %, it may be difficult to form a coating layer with a target thickness. When the amount of the polymer is more than 50 weight %, the uniformity of the coating layer may be degraded. The weight-average molecular weight (Mw) of the polymer is 2,000 to 50,000, preferably 4,000 to 10,000. When the Mw of the polymer is less than 2,000, it may be difficult to form a uniform coating layer and thermal stability may be reduced. When the Mw of the polymer is more than 50,000, the solubility of the polymer at the developing step may be low and thus the developing time becomes longer.

The PAC used in the present invention contains at least 2, preferably 2 to 8 diazonaphtoquinone (DNQ) groups. The DNQ group of the PAC reacts with hydroxy group (—OH) of the polymer (azo coupling reaction), and DNQ is rearranged when it is exposed to an I-line (365 nm) light source, to generate a solubility difference between an exposed part and an unexposed part. Also, the PAC increases the thermal stability of the patterns because DNQ plays a role of cross-linking agent.

The examples of the PAC include a compound represented by following Formula 4, a compound represented by following Formula 5, a compound represented by following Formula 6 and mixture thereof.

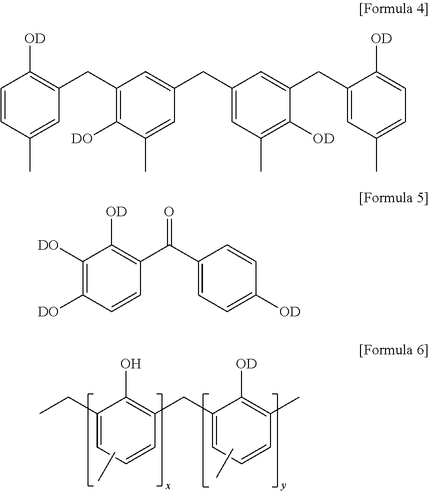

In Formulas 4 to 6, D is a hydrogen atom or

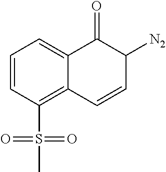

(wherein [symbol] indicates a connecting bond), x and y are mol % of repeating unit constituting the PAC, each independently 20 to 80 mol %, preferably 40 to 60 mol %. At least 2 of D is preferably

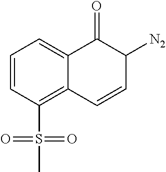

(wherein [symbol] indicates a connecting bond). The Mw of compound represented by Formula 6 is 1,000 to 20,000, preferably 1,100 to 10,000, more preferably 1,200 to 4,800.

The amount of the PAC is 10 to 35 weight %, preferably 15 to 30 weight %, more preferably 20 to 25 weight % with respect to total I-line photoresist composition. When the amount of the PAC is less than 10 weight %, the number of azo coupling is small so that the resist layer of unexposed part may be excessively developed or thermal stability may be degraded. When the amount of the PAC is more than 35 weight %, the number of azo coupling is excessively large, though thermal stability is good, the fine pattern formation at an acid diffusion step cannot be accomplished.

The organic solvent used in the present invention is an organic solvent which is used in the conventional photoresist composition, without the limitation, and the examples of the organic solvent include n-butyl acetate (NBA), ethylactate (EL), gamma-butyrolactone (GBL), propylene glycol monoethyl ether acetate (PGMEA), propylene glycol monomethyl ether (PGME), and mixture thereof.

The amount of the organic solvent is the remainder, subtracted from the total I-line photoresist composition except for the polymer and the PAC.

The I-line photoresist composition of the present invention further comprises additives such as a cross-linking agent or a surfactant as occasion demands.

The cross-linking agent used in the present invention enhances a thermal stability of patterns in forming the patterns. As the cross-linking agent, used is a compound containing at least one benzene structure and substituted with at least two hydroxy groups, for example, 1,4-dihydroxybenzene, 1,5-dihydroxynaphthalene, 1,6-dihydroxynaphthalene, 2,6-dihydroxynaphthalene, bisphenol A, 9,9′-dihydroxyfullerene and mixture thereof. The amount of the cross-linking agent is 1 to 15 weight parts, preferably 3 to 10 weight parts, more preferably 5 to 8 weight parts with respect to 100 weight parts of I-line photoresist composition. When the amount of the cross-linking agent is less than 1 weight part, there is no improvement on the thermal stability. When the amount of the cross-linking agent is more than 15 weight parts, it is difficult to form an uniform coating layer.

The surfactant of the present invention is used for increasing coating uniformity of the I-line photoresist composition, and a conventional surfactant can be used. As the surfactant which can be used in the present invention, there are anionic surfactant, cationic surfactant, amphoteric surfactant or mixture thereof. For example, alkylbenzene sulfonate type, higher amine halide, quaternary ammonium salt type, alkylpyridinium salt type, amino acid type, sulfone imide type, and sulfonamide type surfactants, or mixtures thereof can be used. The amount of the surfactant is 0.01 to 5, preferably 0.1 to 1 weight part to 100 weight part of total I-line photoresist composition. If the amount of the surfactant is less than 0.01 weight part, the coating uniformity during the film formation may decline, and if the amount of the surfactant is more than 5 weight parts, the quality of photoresist layer may be degraded by bubbles generated from the surfactant during the formation of the photoresist layer or the pattern loss by an excess surfactant may be happened during the developing of the photoresist patterns.

The pattern formation using I-line photoresist composition of the present invention is based on a resist contrast difference (developing rate difference) by the PAC, like the conventional I-line photoresist composition. Since the protection group is introduced in a polymer of the present I-line photoresist composition, resist solubility difference becomes larger by a deprotection reaction of the protection group using the acid catalyst in forming patterns. Also, unlike the conventional I-line photoresist composition, the acid diffusion process can be applied to the patterns formed without the introduction of additional instruments so that line width of patterns can be down-scaled from 1 μm to 0.2 μm.

The method of forming fine photoresist patterns according to the present invention includes a step of forming first patterns through a resist contrast difference by the PAC, which is the conventional method using the conventional I-line photoresist composition, a step of forming the acid diffusion layer over the first patterns by coating, and a step of heating and developing the acid diffusion layer to form fine patterns. In detail, the method of forming fine photoresist patterns through the acid diffusion comprises (a) a step of coating the I-line photoresist composition of the present invention over the wafer on which a layer to be etched is formed, then heating (soft-baking) the wafer to form the photoresist layer, (b) a step of exposing the photoresist layer to I-line stepper and heating (post exposure baking: PEB) the photoresist layer, (c) developing the photoresist layer to form photoresist patterns, (d) coating a composition for the acid diffusion layer over the photoresist patterns to form the acid diffusion layer, and (e) heating and developing the photoresist patterns with the acid diffusion layer to reduce the line width of the photoresist patterns.

In the method of forming the fine photoresist patterns, the temperature at the soft-baking step is 80 to 130° C., preferably 100 to 110° C., and the temperature at the post exposure baking step is 80 to 130° C., preferably 100 to 120° C. As the developing solution, 2.38 wt % tetramethyl ammonium hydroxide (TMAH) aqueous solution, tetrabutyl ammounium hydroxide (TBAH) aqueous solution can be used. As the composition for forming the acid diffusion layer, a conventional composition for forming an acid diffusion layer can be used. For example, the composition for forming the acid diffusion layer comprises: a polymer such as polyvinylpyrrolidone, polyvinylimidazole, polyvinylpyrrolidone-co-imidazole, polyvinylpyrrolidone-co-caprolactam, polyacrylic acid; an acid such as para toluene sulfonic acid, trifluoromethane sulfonic acid, nonafluorobutane sulfonic acid; and basic compound such as triethylamine, trioctylamine. Alternatively, commercially manufactured composition for forming the acid diffusion layer can be used in the present invention. The heating temperature after forming the acid diffusion layer is 90 to 180° C., preferably 100 to 150° C., heating time is 50 to 180 seconds, preferably 60 to 90 seconds. As the developing solution, 2.38 weight % of tetramethyl ammounium hydroxide (TMAH) aqueous solution, tetrabutyl ammounium hydroxide (TBAH) aqueous solution.

The photoresist patterns formed by using the I-line photoresist composition of the present invention has higher thermal stability than that formed by the conventional I-line photoresist composition. The enhanced thermal stability results from that the present photoresist composition comprises a PAC containing at least 2 DNQ groups and during the forming the patterns, DNQ group plays a role of the cross-linking agent by reacting with a hydroxyl group in the polymer to guide the azo coupling reaction.

In general, DSA (directed self assembly) lithography comprises steps of (i) coating on a silicon wafer polystyrene-co-metamethyl acrylic acid of neutral layer to form a directed self assembly layer, (ii) forming a photoresist layer over the wafer on which the directed self assembly layer is formed, (iii) exposing and developing the photoresist layer to form guide patterns (1^{st} pattern), (iv) coating on the wafer having the guide patterns BCP dissolved in toluene to form a BCP coating layer, and (v) heating the wafer at a temperature over a glass transition temperature (Tg) of BCP (for example 240° C. for 1 hour and more) and rearranged to obtain the directed self assembly patterns with an ordered orientation. In the step (V), owing to the surface polarity of the guide patterns, the part of BCP having relatively strong polarity is located on the surface of the guide patterns, the other part of BCP having relatively weak polarity is distantly located from the guide patterns. Thus the directed self assembly of BCP is secured.

In the DSA lithography, when the reflow of the guide patterns is generated, the guide patterns are not perpendicular to the wafer and thereby the directed self assembly patterns cannot be vertical to the wafer. Accordingly, for forming fine patterns by using the DSA lithography, it is required the guide patterns which has good thermal stability not to generate the reflow. The patterns formed by using the conventional I-line photoresist composition have poor thermal stability so that they are not suitable as the guide patterns. However, the patterns formed by using the present I-line photoresist composition has excellent thermal stability so that there is no reflow at a high temperature (for example 200 to 250° C.) and they are suitable as the guide patterns. In addition, the I-line photoresist composition makes the fine pattern formation through the acid diffusion process possible so that it is useful as the composition for forming the guide patterns of the DSA lithography of high integration degree.

Hereinafter, the preferable examples are provided for better understanding of the present invention. However, the present invention is not limited by the following examples.

### Manufacturing Example 1

### Preparation of the Polymer Represented by Formula 2a

30.4 g (0.19 mol) of acetic acid 4-vinyl-phenyl ester, 12.0 g (0.06 mol) of 1-(1-ethoxy-ethoxy)-4-vinyl-benzene, and 2.05 g of azobis(isobutyronitrile) (AIBN) were added to a reactor with a reflux nitrogen and dissolved in 200 g of methanol, and the polymerization was carried out at 80° C. for 24 hours. After the completion of the polymerization, the reactant was added slowly to excess heptane to precipitate product, and then the product was dried with a dry oven. Then the product was dissolved in methanol. 12.5 g of 28% ammonia water was added to the dissolved product and the temperature of reactor was raised to 50° C., and then the reaction was carried out for 12 hours. After the completion of the reaction, the resultant was slowly dropped to de-ionized water to precipitate the polymer. The precipitated polymer was dried with the dry oven at 50° C. for 24 hours, to prepare 29.7 g of the polymer (a: 75 mol %, b: 25 mol %) represented by Formula 2a (yield: 86%). The weight-average and polydispersity (PD) of the prepared polymer were measured by GPC (Gel Permeation Chromatography) (Mw=12,030, PD=1.85).

### Manufacturing Example 2

### Preparation of the Polymer Represented by Formula 2b

Except for using 15.4 g (0.06 mol) of 1-(1-cyclohexyloxy-ethoxy)-vinyl-benzene instead of 12.0 g (0.06 mol) of 1-(1-ethoxy-ethoxy)-4-vinyl-benzene, 30.7 g of the polymer (a: 75 mol %, b: 25 mol %) represented by formula 2b was prepared by the same manner as the Manufacturing Example 1 (Yield: 81%, Mw=10,010, PD=1.82).

### Manufacturing Example 3

### Preparation of the Polymer Represented by Formula 2c

Except for using 32.4 g (0.2 mol) of acetic acid 4-vinyl-phenyl ester and 9.1 g (0.05 mol) of 2-methyl-acrylic acid 1-ethyl-cyclopentyl ester instead of 30.4 g (0.19 mol) of acetic acid 4-vinyl-phenyl ester and 12.0 g (0.06 mol) of 1-(1-ethoxy-ethoxy)-4-vinyl-benzene, 24.9 g of the polymer (a: 80 mol %, b: 20 mol %) represented by formula 2c was prepared by the same manner as the Manufacturing Example 1 (Yield: 75%, Mw=12,610, PD=1.90).

### Manufacturing Example 4

### Preparation of the Polymer Represented by Formula 2d

Except for using 7.1 g (0.05 mol) of 2-methyl-acrylic acid tetrabutyl ester instead of 9.1 g (0.0 5 mol) of 2-methyl-acrylic acid 1-ethyl-cyclopentyl ester, 25.2 g of the polymer (a: 80 mol %, b: 20 mol %) represented by formula 2d was prepared by the same manner as the Manufacturing Example 3 (Yield: 81%, Mw=10,620, PD=1.75).

### Manufacturing Example 5

### Preparation of the Polymer Represented by Formula 2e

Except for using 6 g (0.03 mol) of 1-(1-ethoxy-ethoxy)-4-vinyl-benzene and 3.0 g (0.03 mol) of alphamethyl-styrene instead of 12.0 g (0.06 mol) of 1-(1-ethoxy-ethoxy)-4-vinyl-benzene, 28.0 g of the polymer (c: 75 mol %, d and e: 12.5 mol %) represented by formula 2e was prepared by the same manner as the Manufacturing Example 1 (Yield: 88%, Mw=11,920, PD=1.88).

### Manufacturing Example 6

### Preparation of the Polymer Represented by Formula 2f

Except for using 4.3 g (0.03 mol) of 2-methyl-acrylic acid tetrabutyl ester instead of 6 g (0.03 mol) of 1-(1-ethoxy-ethoxy)-4-vinyl-benzene, 28.1 g of the polymer (c: 75 mol %, d and e: 12.5 mol %) represented by formula 2f was prepared by the same manner as the Manufacturing Example 5 (Yield: 92%, Mw=12,720, PD=1.83).

### Examples 1-1 to 1-10 and Comparative Example 1

### Preparation of the Photoresist Composition

As shown in the following Table 1, polymers represented by Formulas 2a to 2f (Manufacturing Examples 1 to 6) or novolac resin (Mw=4,600), the PAC of Formulas 4 to 6 (in following Table 1, the number in the round bracket beside the Formula number indicates the number of DNQ group contained in the polymer) and the surfactant (FC4430, made in 3M) were completely dissolved in a solvent of PGMEA, PGME and filtered by 0.2 μm disk filter to prepare composition for forming negative type photoresist patterns.

TABLE 1

| | Polymer | | | | | | | |
|---|---|---|---|---|---|---|---|---|
| | Manufacturing | | PAC | | Surfactant | | Organic Solvent | |
| | Example | amount | Formula | amount | Compound | amount | PGMEA | PGME |
| Example 1-1 | 1 | 7.5 g | 4(4) | 2.5 g | FC 4430 | 0.1 g | 40 g | — |
| Example 1-2 | 2 | 7.5 g | 4(4) | 2.5 g | FC 4430 | 0.1 g | 40 g | — |
| Example 1-3 | 3 | 7.5 g | 4(4) | 2.5 g | FC 4430 | 0.1 g | 40 g | — |
| Example 1-4 | 4 | 7.5 g | 4(4) | 2.5 g | FC 4430 | 0.1 g | 40 g | — |
| Example 1-5 | 5 | 7.5 g | 4(4) | 2.5 g | FC 4430 | 0.1 g | 40 g | — |
| Example 1-6 | 6 | 7.5 g | 4(4) | 2.5 g | FC 4430 | 0.1 g | 40 g | — |
| Example 1-7 | 1 | 7.5 g | 5(4) | 2.6 g | FC 4430 | 0.1 g | 40 g | — |
| Example 1-8 | 1 | 7.5 g | 6(4) | 2.7 g | FC 4430 | 0.1 g | 40 g | — |
| Example 1-9 | 1 | 7.5 g | 5(2) | 2.8 g | FC 4430 | 0.1 g | 40 g | — |
| Example 1-10 | 1 | 7.5 g | 6(8) | 2.9 g | FC 4430 | 0.1 g | 25 g | 15 g |
| Comparative | Novolac resin | 7.5 g | 4(4) | 2.5 g | FC 4430 | 0.1 g | 40 g | — |
| Example 1 | | | | | | | | |

### Examples 2-1 to 2-10 and Comparative Example 2

### Formation of Patterns of the Semiconductor Device and Evaluation Thereof

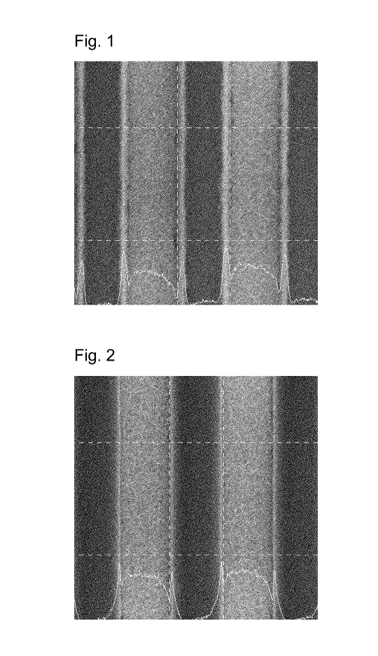

The photoresist composition prepared by each of Examples 1-1 to 1-10 and Comparative Example 1 was spin-coated on the top of the wafer with a thickness of 1 μm, the spin-coated wafer was soft-baked in an oven or on a heating plate at 100° C. for 90 seconds to form the photoresist layer. The wafer with the photoresist layer was exposed to an I-line stepper having 0.57 aperture number (NSR-2205, made by Nikon) and then was post exposure baked in an oven or on a heating plate at 110° C. for 90 seconds. The baked wafer was dipped in 2.38 wt % tetramethyl ammonium hydroxide (TMAH) aqueous solution for 120 seconds for developing to form a line and space pattern having a line width of 1 μm. The line width prepared was measured with a Scanning Electron Microscope CD-SEM (S-8820, made by Hitachi) and was shown in the following Table 2. Photograph of Scanning Electron Microscope of a photoresist pattern according to Example 2-1 of the present invention was shown in FIG. 1.

TABLE 2

| | Expose dose | Line width |
|---|---|---|
| | (msec) | size (μm) |
| Example 2-1 | 180 | 0.998 |
| Example 2-2 | 200 | 0.983 |
| Example 2-3 | 220 | 1.024 |
| Example 2-4 | 210 | 1.011 |
| Example 2-5 | 200 | 1.003 |
| Example 2-6 | 250 | 0.991 |
| Example 2-7 | 260 | 0.989 |
| Example 2-8 | 280 | 0.993 |
| Example 2-9 | 120 | 1.031 |
| Example 2-10 | 320 | 0.980 |
| Comparative | 180 | 1.020 |
| Example 2 | | |

### Examples 3-1 to 3-10 and Comparative Example 3

### Formation of Patterns of the Semiconductor Device and Evaluation Thereof

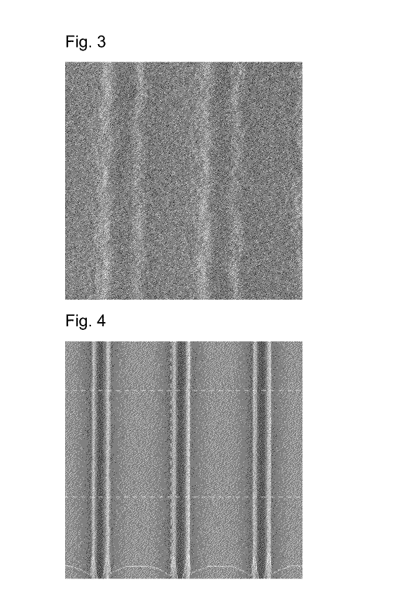

To test the thermal stability of the photoresist patterns formed in the Examples 2-1 to 2-10 and Comparative Example 2 (wherein more little the variation of line width of pattern (LCD) is, more good the thermal stability thereof is), the wafer on which the photoresist patterns formed in the Examples 2-1 to 2-10 and Comparative Example 2 was heated in an oven or on a heating plate at 240° C. for 60 seconds. The line width of the patterns after the heating was measured with the Scanning Electron CD-SEM (S-8820, made by Hitachi) and the results was shown in the following Table 3. Photographs of Scanning Electron Microscope of photoresist patterns according to Example 3-1 of the present invention and Comparative Example 3 were shown in FIG. 2 and FIG. 3, respectively.

TABLE 3

| | Line width before | Line width after | Line width variation |
|---|---|---|---|
| | heating (μm) | heating (μm) | (ΔCD(μm)) |
| Example 3-1 | 0.998 | 1.01 | 0.012 |
| Example 3-2 | 0.983 | 1.001 | 0.018 |
| Example 3-3 | 1.024 | 1.044 | 0.02 |
| Example 3-4 | 1.011 | 1.023 | 0.012 |
| Example 3-5 | 1.003 | 1.021 | 0.018 |
| Example 3-6 | 0.991 | 0.998 | 0.007 |
| Example 3-7 | 0.989 | 0.999 | 0.01 |
| Example 3-8 | 0.993 | 1.02 | 0.027 |
| Example 3-9 | 1.031 | 1.034 | 0.003 |
| Example 3-10 | 0.98 | 1.006 | 0.026 |
| Comparative | 1.02 | — | 1.02 |
| Example 3 | | | |

### Examples 3-1 to 3-10 and Comparative Example 3

### Formation of Fine Patterns of the Semiconductor Device and Evaluation Thereof

The acid diffusion material (C-060, made by Dongjin Semichem Co., Ltd.) was coated on the wafer on which the photoresist patterns formed in the Examples 2-1 to 2-10 and Comparative Example 2 were formed, and then the wafer was baked in an oven or on a heating plate at 130° C. for 60 seconds. The baked wafer was dipped in 2.38 wt % tetramethyl ammonium hydroxide (TMAH) aqueous solution for 60 seconds for developing to form a line and space pattern having scale-down line width. The reduced line width was measured with a Scanning Electron Microscope CD-SEM (S-8820, made by Hitachi) and was shown in the following Table 4. Photograph of Scanning Electron Microscope of a photoresist pattern (fine pattern) according to Example 4-1 of the present invention was shown in FIG. 4.

TABLE 4

| | Line width before | Line width after | Line width variation |
|---|---|---|---|
| | scale-down (μm) | scale-down (μm) | (ΔCD(μm)) |
| Example 4-1 | 0.998 | 0.426 | 0.572 |
| Example 4-2 | 0.983 | 0.443 | 0.54 |
| Example 4-3 | 1.024 | 0.462 | 0.562 |
| Example 4-4 | 1.011 | 0.455 | 0.556 |
| Example 4-5 | 1.003 | 0.458 | 0.545 |
| Example 4-6 | 0.991 | 0.492 | 0.499 |
| Example 4-7 | 0.989 | 0.521 | 0.468 |
| Example 4-8 | 0.993 | 0.569 | 0.424 |
| Example 4-9 | 1.031 | 0.368 | 0.663 |
| Example 4-10 | 0.98 | 0.785 | 0.195 |
| Comparative | 1.02 | 0.989 | 0.031 |
| Example 4 | | | |

As shown above, the I-line photoresist composition of the present invention comprises the PAC containing at least 2 DNQ groups, thus it has superior thermal stability (Examples 3-1 to 3-10) in comparison with the conventional I-line photoresist composition (Comparative Example). Also, the I-line photoresist composition of the present invention contains a polymer including the protection group, thus the fine pattern formation using the acid diffusion layer can be effectively performed (Examples 4-1 to 4-10).

1. An I-line photoresist composition comprising:
a polymer containing 1 to 99 mol % of repeating unit selected from a group consisting of 1 to 99 mol % of repeating unit represented by a following Formula 1, a repeating unit represented by a following Formula 2, a repeating unit represented by a following Formula 3 and mixture thereof;
a photo active compound containing at least two diazonaphtoquinone (DNQ) groups; and
an organic solvent, 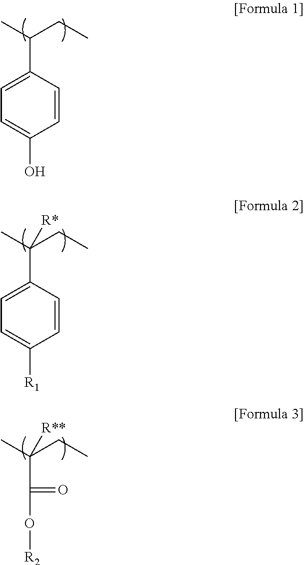
wherein in Formulas 2 and 3, R* and R** each is independently a hydrogen atom or a methyl group, R₁ is a hydrogen atom or linear, branch or cyclic hydrocarbonyl group of 3 to 15 carbon atoms, which contains 1 to 4 oxygen atoms or does not contains, R₂ is linear, branch or cyclic hydrocarbonyl group of 1 to 30 carbon atoms, which contains 1 to 4 oxygen atoms or does not contains.

2. The I-line photoresist composition of claim 1, wherein the polymer is selected from a group consisting of polymers represented by following Formulas 1a to 1d, 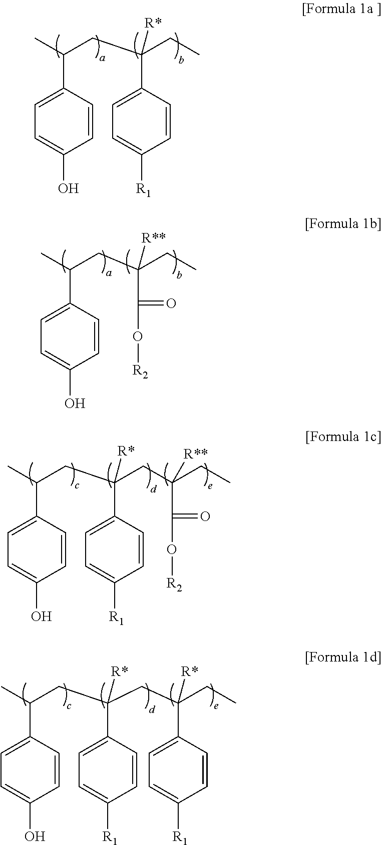
wherein in Formulas 1a to 1d, R*, R**, R₁ and R₂ each is independently the same as defined in the Formulas 2 and 3, a, b, c, d and e represent mol % of repeating unit constituting the polymer, a is 1 to 99 mol %, b is 1 to 99 mol %, c, e and f each is 1 to 98 mol %.

3. The I-line photoresist composition of claim 1, wherein the polymer is selected from a group consisting of polymers represented by following Formulas 2a to 2f, 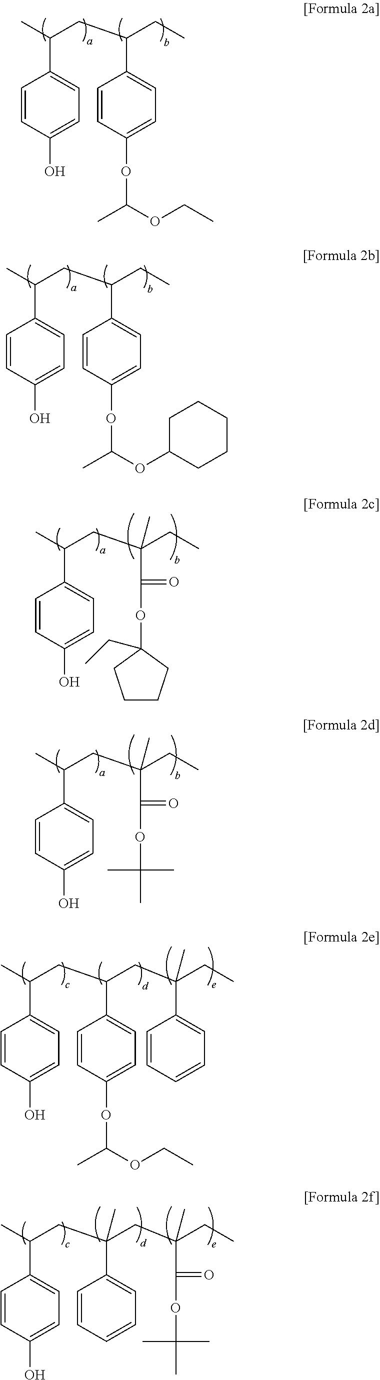
wherein in Formulas 2a to 2f, a, b, c, d and e represent mol % of repeating unit constituting the polymer, a and b each is independently 1 to 99 mol %, c, d and e each is independently 1 to 98 mol %.

4. The I-line photoresist composition of claim 1, wherein the photo active compound is selected from a group consisting of a compound represented by following Formula 4, a compound represented by following Formula 5, a compound represented by following Formula 6 and mixture thereof, 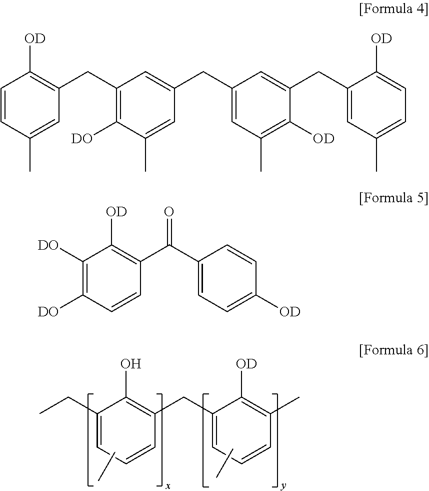
wherein in Formulas 4 to 6, D is a hydrogen atom or 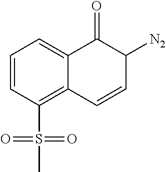
(wherein [symbol] indicates a connecting bond), x and y are mol % of repeating unit constituting the PAC, each independently 20 to 80 mol %.

5. The I-line photoresist composition of claim 1, wherein the organic solvent is selected from a group consisting of n-butylacetate (nBA), ethylactate (EL), gamma-butyrolactone (GBL), propylene glycol monoethyl ether acetate (PGMEA), propylene glycol monomethyl ether (PGME) and mixture thereof.

6. The I-line photoresist composition of claim 1, wherein the amount of the polymer is 5 to 50 weight %, the amount of the photo active compound is 10 to 35% with respect to total I-line photoresist composition, and the amount of the organic solvent is the remainder.

7. The I-line photoresist composition of claim 1, further comprising an additive selected from a group consisting of a cross-linking agent, a surfactant and mixture thereof, wherein the amount of the cross-linking agent is 1 to 15 weight parts with respect to 100 weight parts of the I-line photoresist composition and the amount of the surfactant is 0.01 to 5 weight parts with respect to 100 weight parts of the I-line photoresist composition.

8. The I-line photoresist composition of claim 7, wherein the cross-linking agent is selected from a group consisting of 1,4-dihydroxybenzene, 1,5-dihydroxynaphthalene, 1,6-dihydroxynaphthalene, 2,6-dihydroxynaphthalene, bisphenol A, 9,9′-dihydroxyfullerene and mixture thereof.

9. A method for forming fine photoresist patterns, comprising the steps of:
coating one of I-line photoresist compositions according to claim 1 over a semiconductor substrate on which a layer to be etched is formed, and heating the substrate to form a photoresist layer;
exposing the photoresist layer using a given photomask and I-line stepper and heating the exposed photoresist layer;
developing the exposed and heated photoresist layer to form photoresist patterns;
coating a composition for an acid diffusion layer over the photoresist patterns to form the acid diffusion layer; and
heating and developing the photoresist pattern with the acid diffusion layer to reduce a line width of the photoresist patterns.
